(19) United States
(12) Patent Application Publication
(10) Pub. No.: US 2017/0200814 A1
(43) Pub. Date: Jul. 13, 2017

(54) MANUFACTURING METHOD OF METAL OXIDE SEMICONDUCTOR THIN FILM TRANSISTOR

(71) Applicant: Chunghwa Picture Tubes, Ltd., Taoyuan City (TW)

(72) Inventors: Hsi-Ming Chang, Taoyuan City (TW); Yen-Yu Huang, Taoyuan City (TW)

(21) Appl. No.: 15/158,595

(22) Filed: May 19, 2016

(30) Foreign Application Priority Data
Jan. 7, 2016 (CN) 201610009186.6

(51) Int. Cl. H01L 29/66; H01L 21/027; H01L 21/02; H01L 29/786

(52) U.S. Cl. CPC H01L 29/66969; H01L 29/7869; H01L 21/0274; H01L 21/02414

(57) ABSTRACT

A manufacturing method of a metal oxide semiconductor thin film transistor is provided. The manufacturing method includes following steps. A gate, a gate insulating layer, a patterned metal oxide semiconductor layer and a conductive layer are formed on a substrate first. Next, a first patterned photoresist layer and two second patterned photoresist layers are formed on the conductive layer. Next, a first etching process is performed and the first patterned photoresist layer is then removed. Next, a second etching process is performed to form a source and a drain, and the second patterned photoresist layers are then removed. The source and the drain of the present invention are formed by performing two etching processes to different portions of the conductive layer respectively. Thus, the metal oxide semiconductor layer is prevented from being influenced by the processes of forming the source and the drain, and the process stability is maintained.

### BACKGROUND OF THE INVENTION

1. Field of the Invention

The present invention generally relates to a manufacturing method of a metal oxide semiconductor thin film transistor, and more particularly, to a manufacturing method of a metal oxide semiconductor thin film transistor with two etching processes that etch different portions of a conductive layer respectively, so as to form a source and a drain.

2. Description of the Prior Art

In recent years, applications of flat display devices are rapidly developed. Electronics, such as televisions, cell phones, mobiles and refrigerators, are installed with flat display devices. Thin film transistor (TFT) is a kind of semiconductor devices commonly used in the flat display device, such as liquid crystal display (LCD), organic light emitting diode (OLED) display and electronic paper (E-paper). The thin film transistor is employed to control voltage and/or current of a pixel of the flat display device for presenting bright, dark, or gray level display effect.

According to different semiconductor materials applied to the thin film transistors, the thin film transistors in current display industries may include amorphous silicon thin film transistors (a-Si TFTs), poly silicon thin film transistors, and metal oxide semiconductor thin film transistors. The process flexibility of the metal oxide semiconductor thin film transistor is better than that of the amorphous silicon thin film transistor, and the electrical mobility of the metal oxide semiconductor thin film transistor is higher than the electrical mobility of the amorphous silicon thin film transistor. Therefore, the metal oxide semiconductor thin film transistor is currently the front-runner in the competition of replacing the amorphous silicon thin film transistor, which is the main stream in the display industry. However, the material and electrical properties of the oxide semiconductor layer tend to be influenced easily by the environment condition and the manufacturing process conditions. Taking the conventional back channel etch (BCE) structure as an example, the metal oxide semiconductor layer may be influenced by the plasma damage when a dry etching process is adopted. Therefore, the electrical properties of the thin film transistor may further be influenced.

### SUMMARY OF THE INVENTION

It is one of the objectives of the present invention to provide a manufacturing method of a metal oxide semiconductor thin film transistor, wherein the source and the drain are formed by performing two etching processes to different portions of the conductive layer respectively, so that the metal oxide semiconductor layer is prevented from being influenced by the processes of forming the source and the drain and the process stability is maintained.

To achieve the purpose described above, an embodiment of the present invention provides a manufacturing method of a metal oxide semiconductor thin film transistor including following steps. First, a substrate is provided. A gate is formed on the substrate, and a gate insulating layer is formed on the gate. A patterned metal oxide semiconductor layer is formed on the gate insulating layer, wherein the metal oxide semiconductor layer partially overlaps the gate. A conductive layer is formed on the patterned metal oxide semiconductor layer. A first patterned photoresist layer and two second patterned photoresist layers are then formed on the conductive layer, wherein the second patterned photoresist layers are respectively disposed at a region predetermined to form a source and a region predetermined to form a drain, and the first patterned photoresist layer is disposed between the second patterned photoresist layers. A first etching process is performed to remove a portion of the conductive layer not covered by the first patterned photoresist layer and the second patterned photoresist layers. The first patterned photoresist layer is removed to expose a portion of the conductive layer disposed between the second patterned photoresist layers. Then, a second etching process is performed to remove a portion of the conductive layer not covered by the second patterned photoresist layers to form the source and the drain. The second patterned photoresist layers are removed.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram illustrating a process flow of a manufacturing method of a metal oxide semiconductor thin film transistor of the present invention.

FIGS. 2-19 are schematic diagrams illustrating a manufacturing method of a metal oxide semiconductor thin film transistor of an embodiment of the present invention, wherein:

FIG. 3 is a schematic diagram illustrating the manufacturing method subsequent to FIG. 2;

FIG. 4 is a schematic diagram illustrating the manufacturing method subsequent to FIG. 3;

FIG. 5 is a schematic diagram illustrating a cross-sectional view taken along a line A-A′ in FIG. 4;

FIG. 6 is a schematic diagram illustrating the manufacturing method subsequent to FIG. 5;

FIG. 7 is a schematic diagram illustrating the manufacturing method subsequent to FIG. 6;

FIG. 8 is a schematic diagram illustrating a cross-sectional view taken along a line A-A′ in FIG. 7;

FIG. 9 is a schematic diagram illustrating the manufacturing method subsequent to FIG. 8;

FIG. 10 is a schematic diagram illustrating a cross-sectional view taken along a line A-A′ in FIG. 9;

FIG. 11 is a schematic diagram illustrating the manufacturing method subsequent to FIG. 10;

FIG. 12 is a schematic diagram illustrating a cross-sectional view taken along a line A-A′ in FIG. 11;

FIG. 13 is a schematic diagram illustrating the manufacturing method subsequent to FIG. 12;

FIG. 14 is a schematic diagram illustrating a cross-sectional view taken along a line A-A′ in FIG. 13;

FIG. 15 is a schematic diagram illustrating the manufacturing method subsequent to FIG. 14;

FIG. 16 is a schematic diagram illustrating a cross-sectional view taken along a line A-A′ in FIG. 15;

FIG. 17 is a schematic diagram illustrating the manufacturing method subsequent to FIG. 16;

FIG. 18 is a schematic diagram illustrating the manufacturing method subsequent to FIG. 17; and

FIG. 19 is a schematic diagram illustrating a cross-sectional view taken along a line A-A′ in FIG. 18.

### DETAILED DESCRIPTION

To provide a better understanding of the present invention to the skilled users in the technology of the present invention, preferred embodiments will be detailed as follows. The preferred embodiments of the present invention are illustrated in the accompanying drawings with numbered elements to elaborate the contents and effects to be achieved. The present invention is not limited to the preferred embodiments.

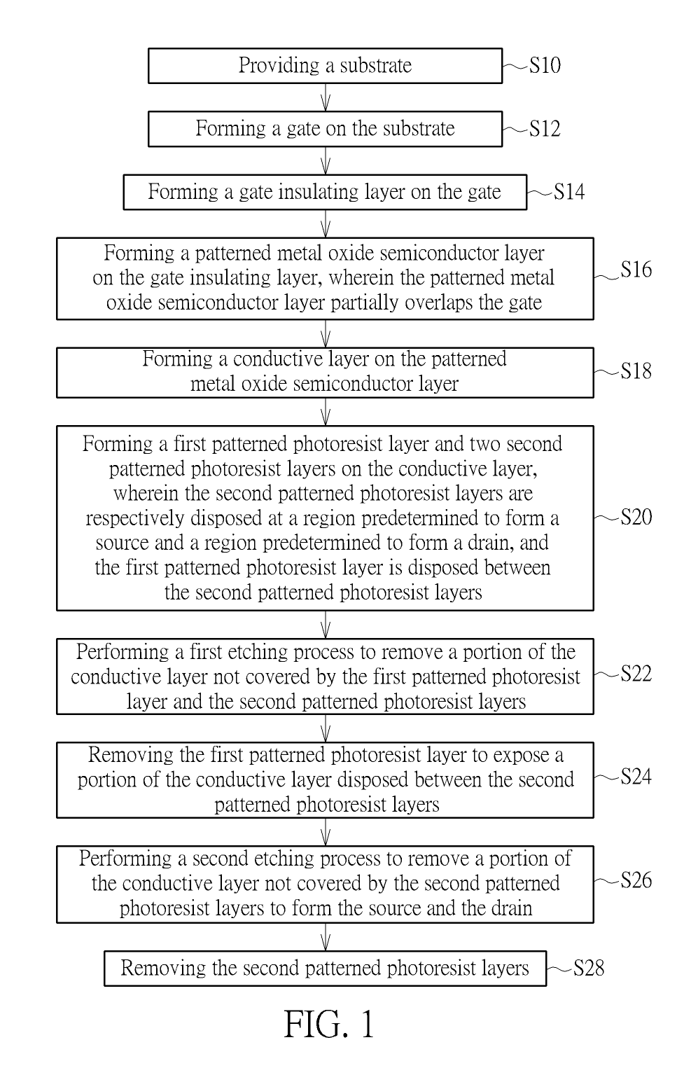

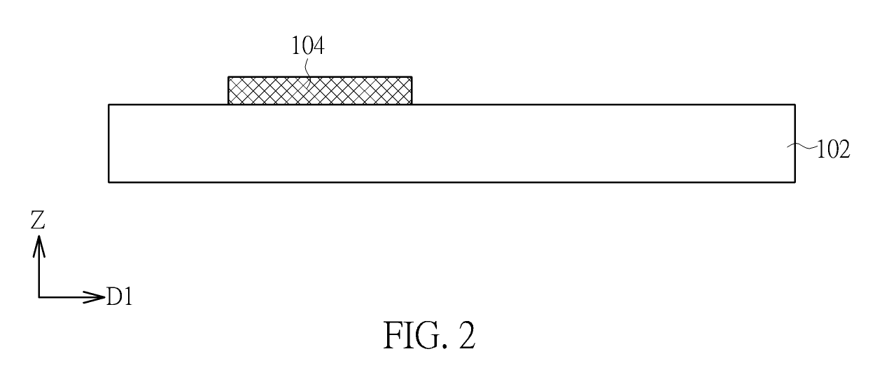

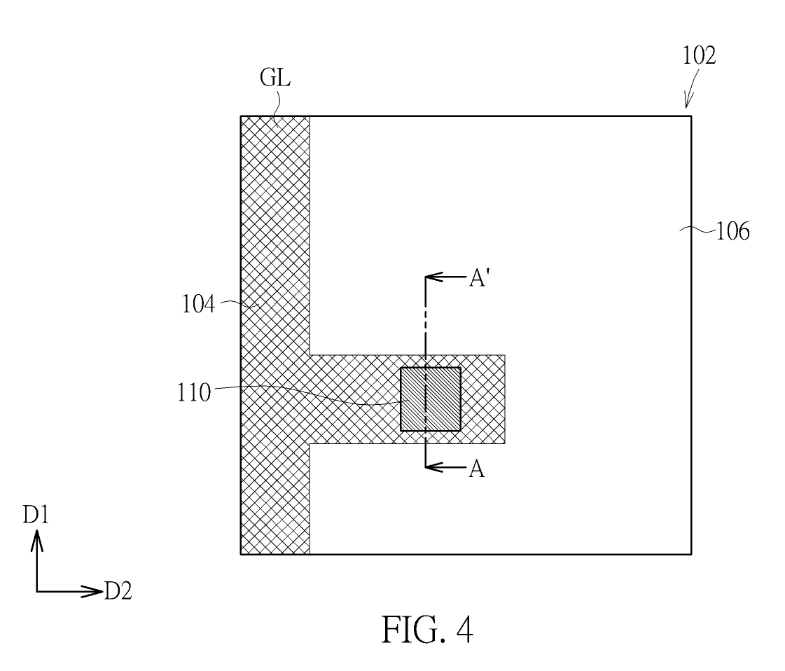

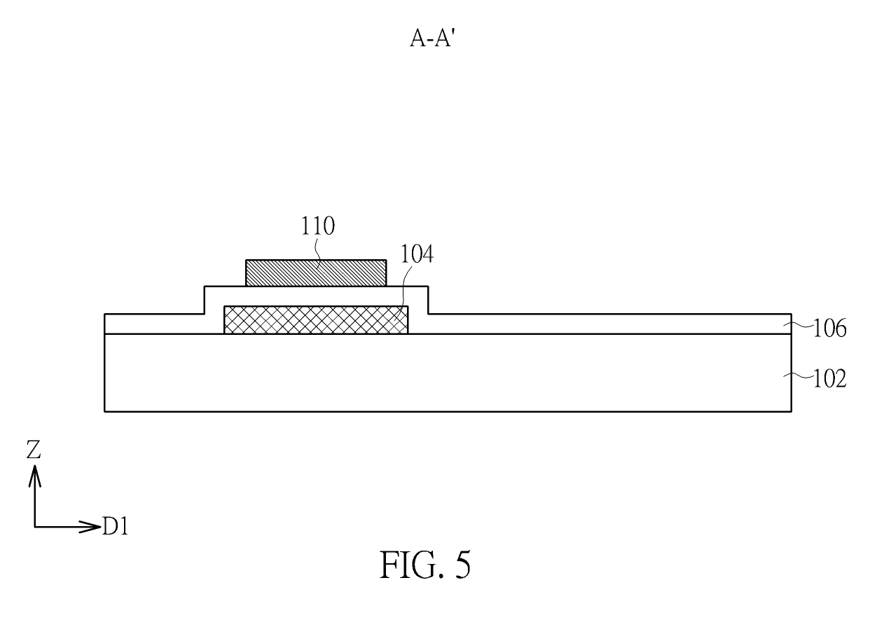

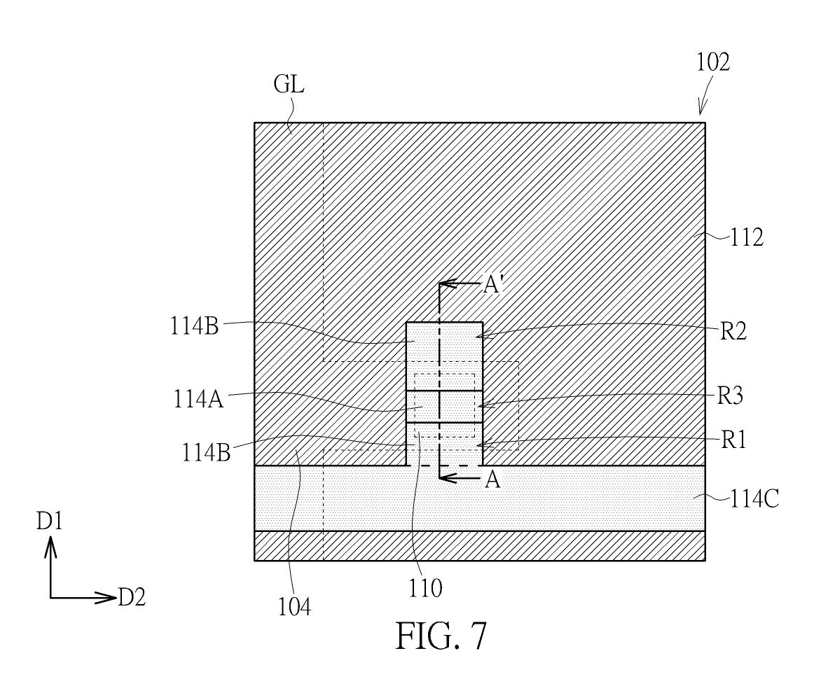

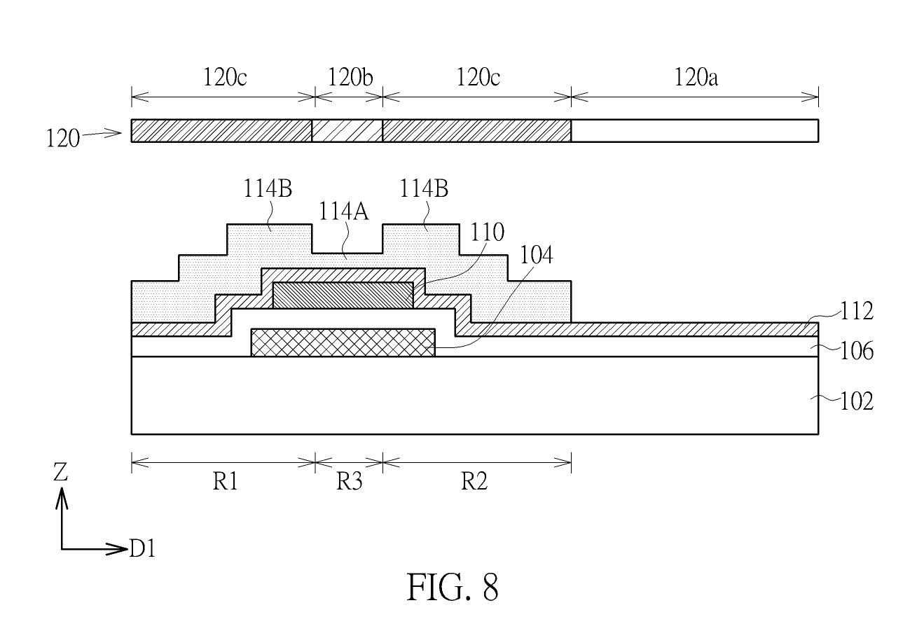

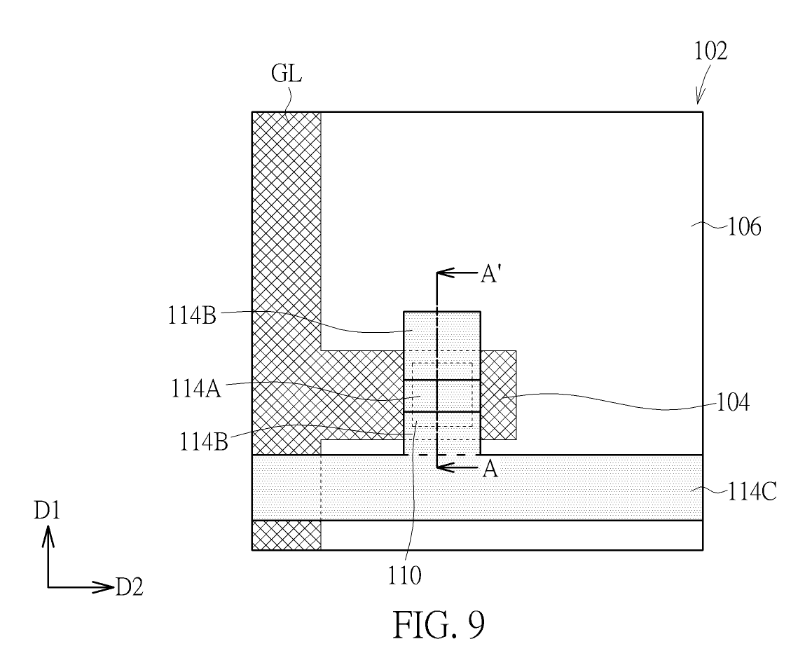

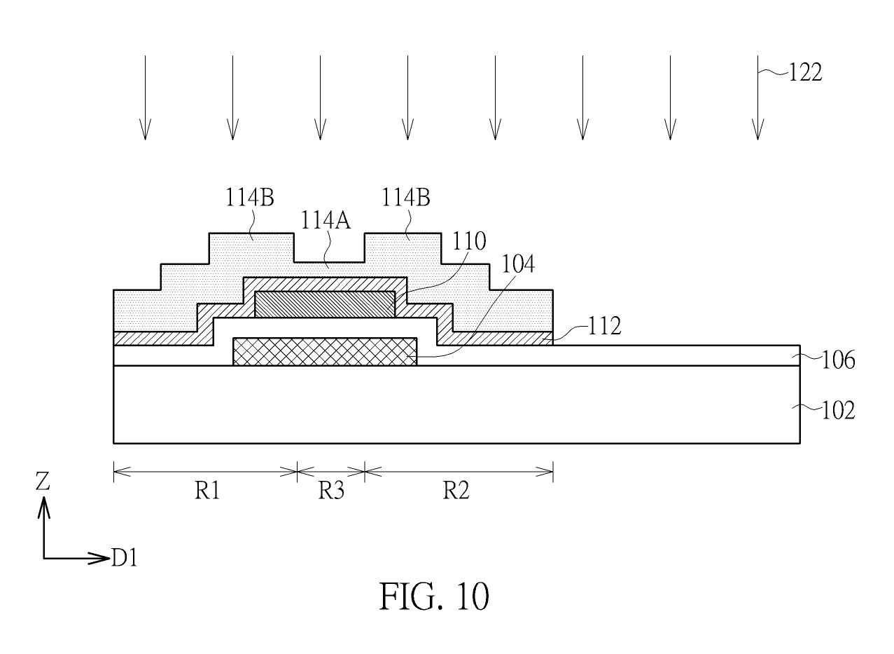

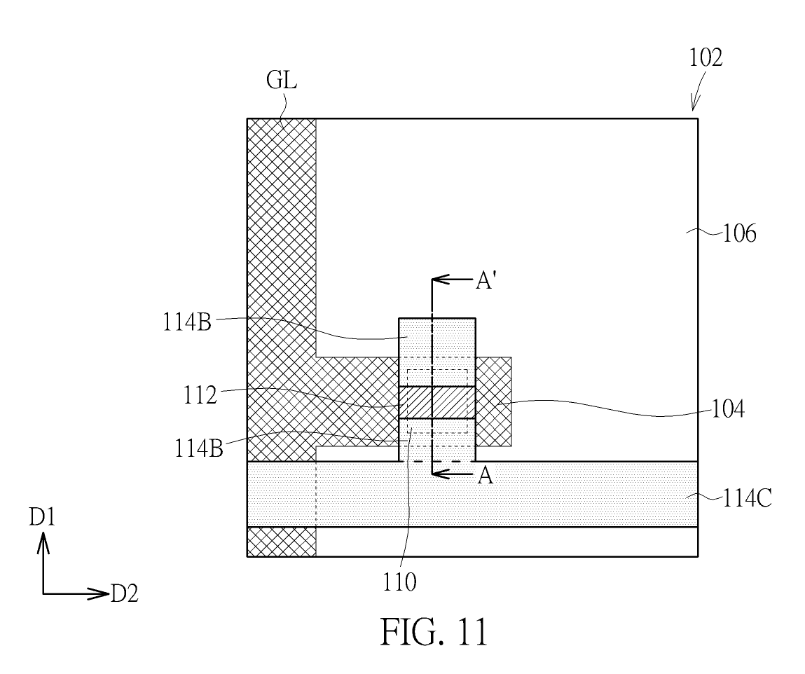

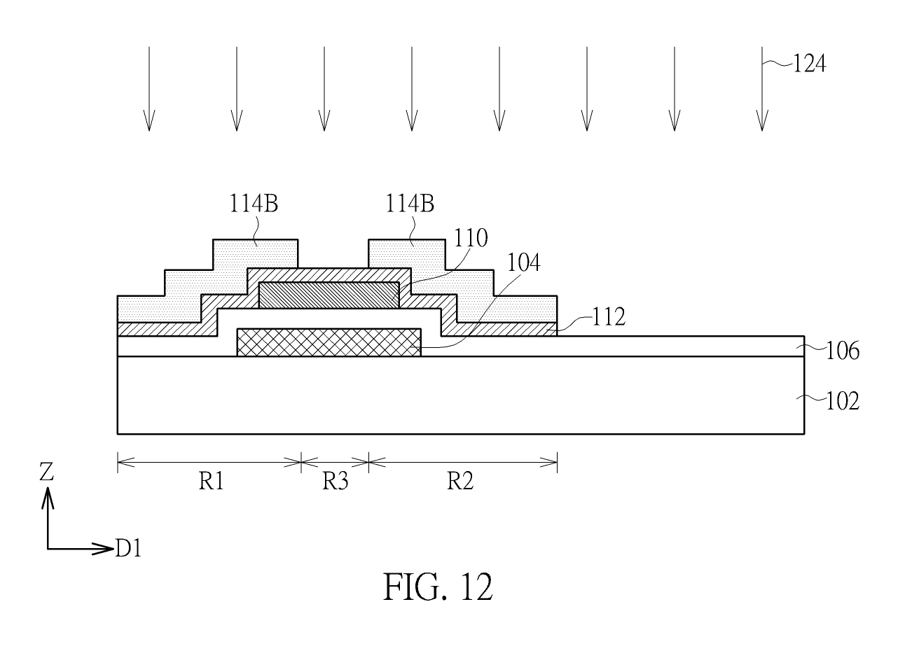

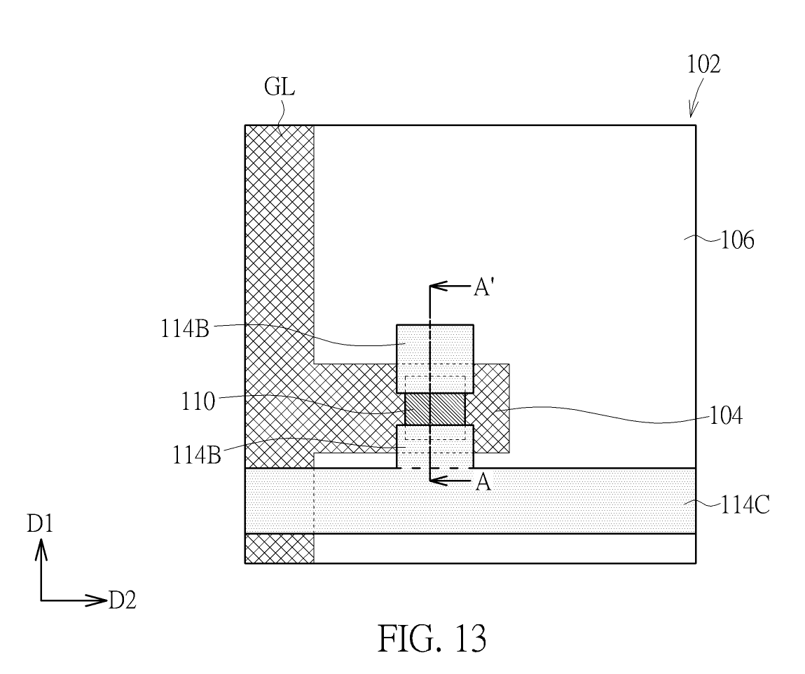

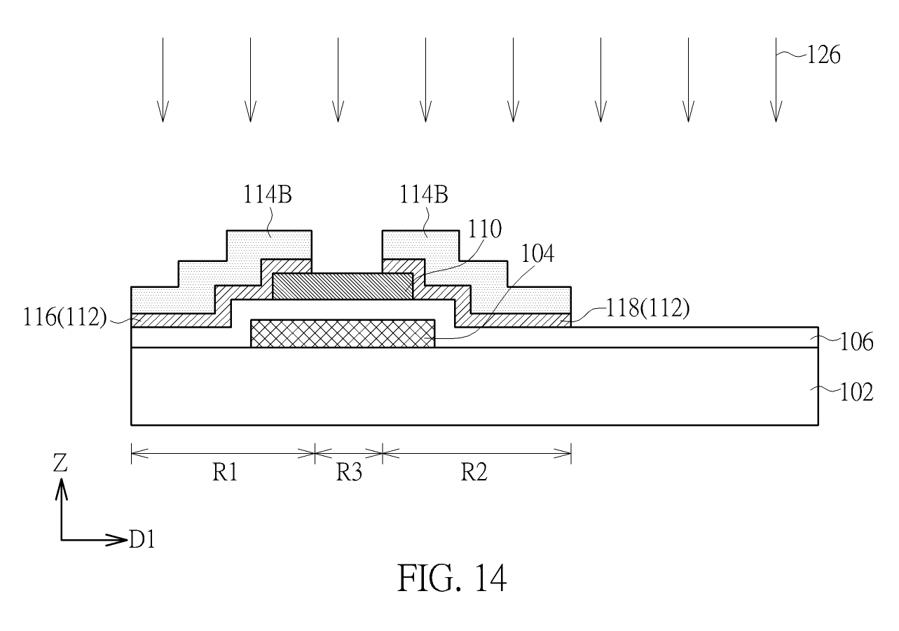

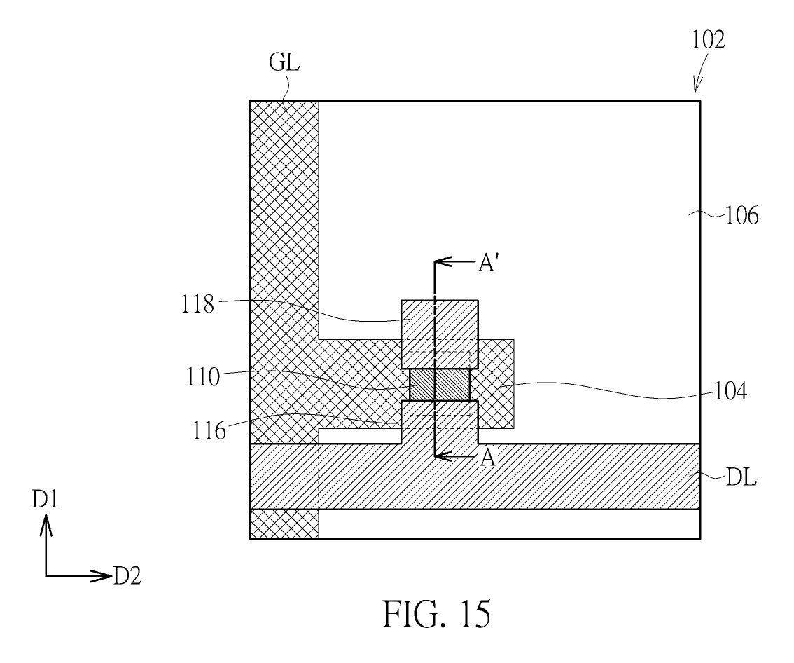

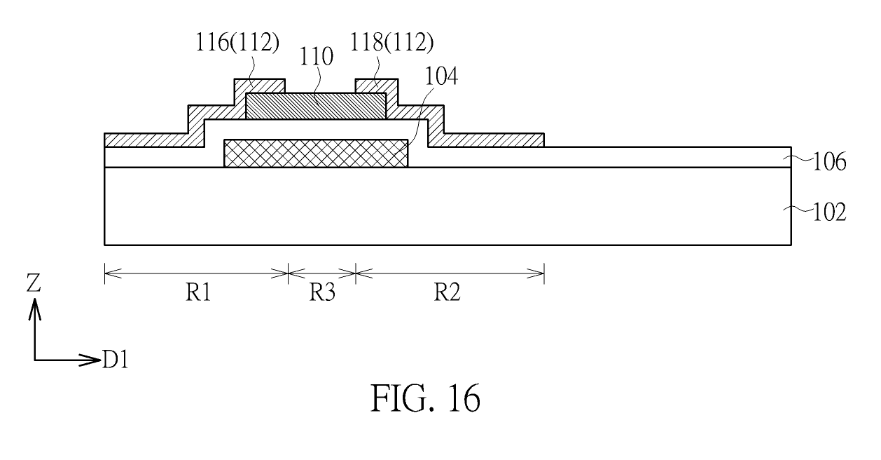

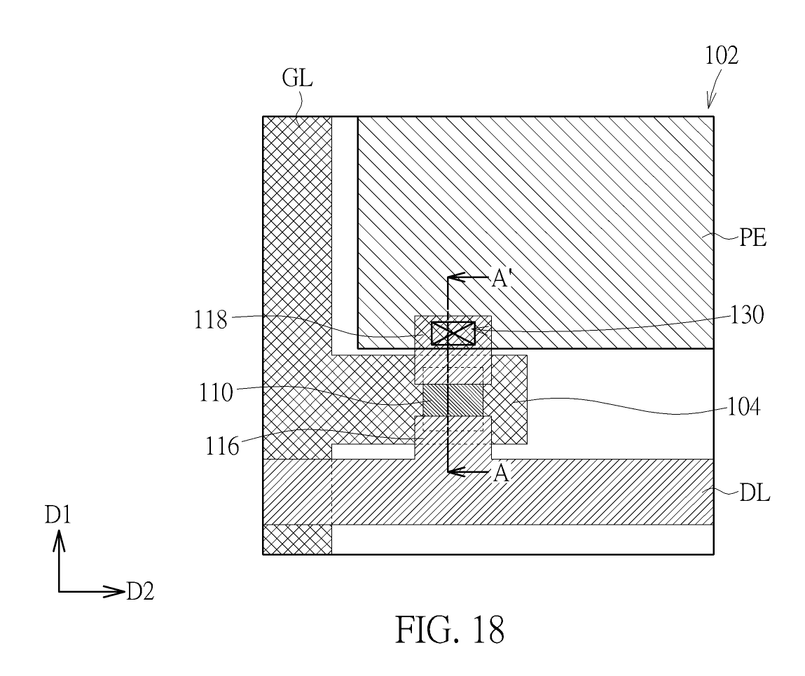

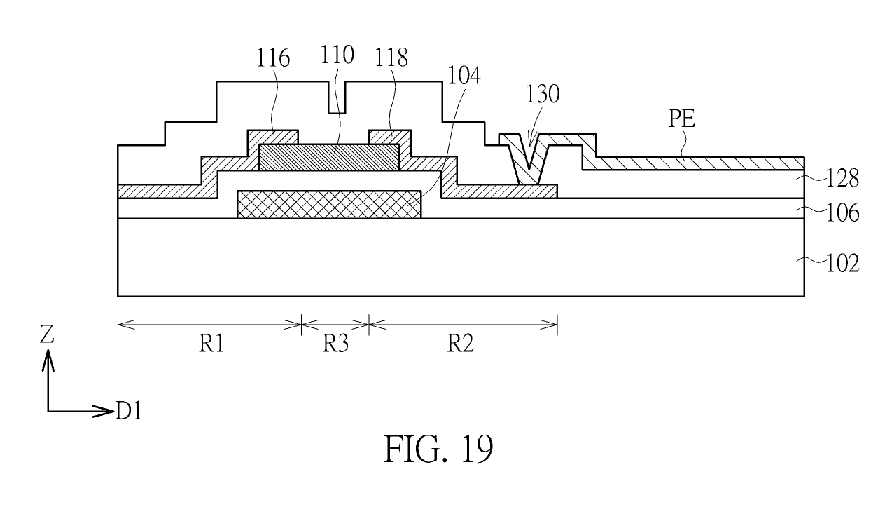

Please refer to FIG. 1 to FIG. 19. FIG. 1 is a schematic diagram illustrating a process flow of a manufacturing method of a metal oxide semiconductor thin film transistor of the present invention. FIGS. 2-19 are schematic diagrams illustrating processes of a manufacturing method of a metal oxide semiconductor thin film transistor of an embodiment of the present invention, wherein FIG. 4, FIG. 7, FIG. 9, FIG. 11, FIG. 13, FIG. 15 and FIG. 18 are schematic diagrams illustrating top views of the device during manufacturing processes, and FIG. 5, FIG. 8, FIG. 10, FIG. 12, FIG. 14, FIG. 16 and FIG. 19 are schematic diagrams respectively illustrating cross-sectional views taken along a line A-A′ in FIG. 4, FIG. 7, FIG. 9, FIG. 11, FIG. 13, FIG. 15 and FIG. 18. The metal oxide semiconductor thin film transistor manufactured by the method of this embodiment is a metal oxide semiconductor thin film transistor that can be applied to a display panel for example, but not limited thereto. As shown in FIG. 1 and FIG. 2, Step S10 of FIG. 1 is performed first, and a substrate 102 is provided. The substrate 102 may include a hard substrate such as a glass substrate or a ceramic substrate, a flexible substrate such as a plastic substrate, or a substrate formed of other suitable materials. The substrate 102 of this embodiment is a glass substrate for example. Then, Step S12 of FIG. 1 is performed, and a gate 104 is formed. For example, the method of forming the gate 104 may include forming a metal layer (not shown) on the substrate 102 first, and performing a photolithography and etching process to the metal layer to form the gate 104 on the substrate 102. The material of the metal layer may include one or more of aluminum, copper, silver, chromium, titanium, molybdenum, a composite layer or an alloy of the above mentioned materials, but not limited thereto.

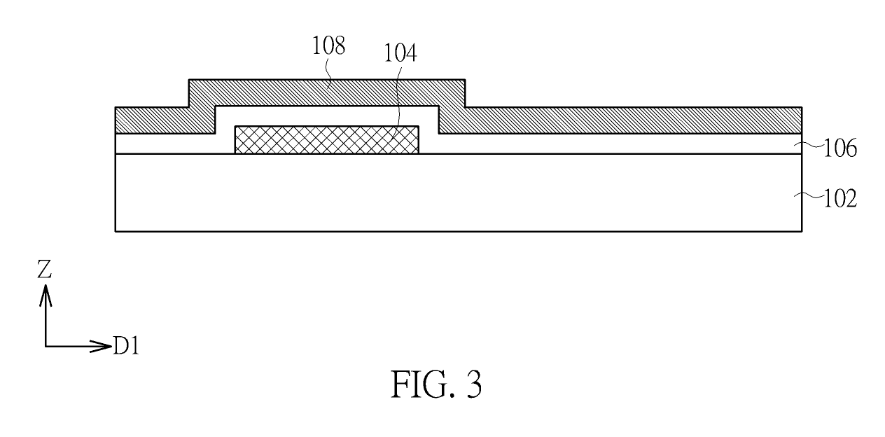

Please refer to FIG. 3 to FIG. 5. Step S14 of FIG. 1 is executed next, and a gate insulating layer 106 is formed on the gate 104 and the substrate 102. The material of the gate insulating layer 106 may include an inorganic insulating material such as silicon oxide, silicon nitride or silicon oxynitride, but not limited thereto. The material of the gate insulating layer 106 may also include an organic insulating material or an organic/inorganic hybrid insulating material. Then, Step S16 is carried out to form a patterned metal oxide semiconductor layer 110 on the gate insulating layer 106. The method of manufacturing the patterned metal oxide semiconductor layer 110 may include depositing a metal oxide semiconductor layer 108 on the gate insulating layer 106 first, and performing a patterning process (such as a photolithography and etching process) to the metal oxide semiconductor layer 108 next, in order to form the patterned metal oxide semiconductor layer 110. As shown in FIG. 4 and FIG. 5, the patterned metal oxide semiconductor layer 110 partially overlaps the gate 104 in a vertical projection direction Z. In other words, the patterned metal oxide semiconductor layer 110 covers a portion of the gate 104. In this embodiment, the material of the metal oxide semiconductor layer 108 is indium gallium zinc oxide (IGZO) for example, but not limited thereto. The material of the metal oxide semiconductor layer 108 may include II-VI compounds (such as zinc oxide, ZnO), II-VI compounds doped with alkaline-earth metals (such as zinc magnesium oxide, ZnMgO), II-VI compounds doped with IIIA compounds (such as indium gallium zinc oxide, IGZO), II-VI compounds doped with VA compounds (such as stannum stibium oxide, SnSbO₂), II-VI compounds doped with VIA compounds (such as zinc selenium oxide, ZnSeO), II-VI compounds doped with transition metals (such as zinc zirconium oxide, ZnZrO), or other oxide semiconductor materials composed of mixtures of the above-mentioned materials, but the present invention is not limited thereto.

The metal oxide semiconductor thin film transistor manufactured by the method of this embodiment can be applied to the display panel, but not limited thereto. For example, at least one gate line GL can be formed on the substrate 102, wherein the gate line GL extends along a first direction D1 and is connected to the gate 104. The gate line GL and the gate 104 may be formed of the same metal layer, and may be formed by the same patterning process together.

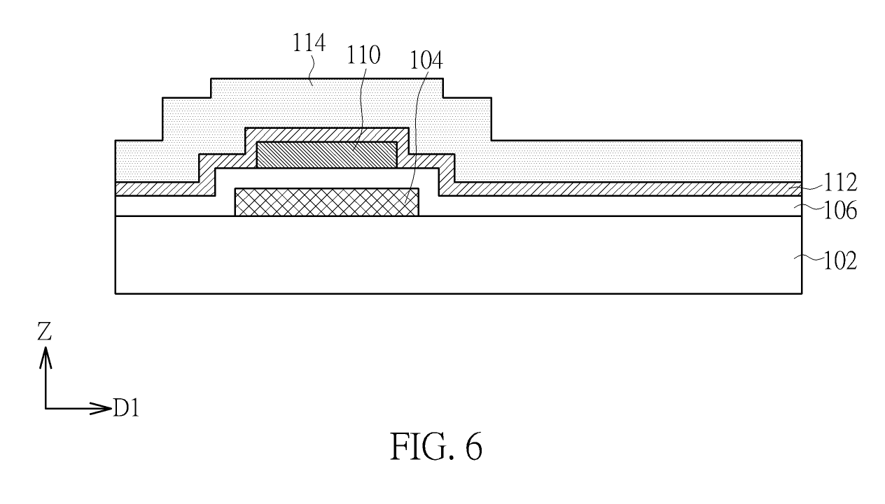

As shown in FIG. 6, Step S18 of FIG. 1 is performed next. A conductive layer 112 is formed on the patterned metal oxide semiconductor layer 110, and a photoresist layer 114 is formed on the conductive layer 112 next. The material of the conductive layer 112 may include metal materials, such as including one or more of aluminum (Al), copper (Cu), silver (Ag), chromium (Cr), titanium (Ti) and molybdenum (Mo), a composite layer of the above-mentioned materials, or an alloy of the above-mentioned materials, but not limited thereto. As shown in FIG. 7 and FIG. 8, Step S20 is performed next. A first patterned photoresist layer 114A and two second patterned photoresist layers 114B are formed on the conductive layer 112, wherein the second patterned photoresist layers 114B are respectively disposed at a region R1 predetermined to form a source and a region R2 predetermined to form a drain on the substrate 102. The first patterned photoresist layer 114A is disposed at a region R3 on the substrate 102, and is disposed between the two second patterned photoresist layers 114B. The first patterned photoresist layer 114A overlaps a portion of the patterned metal oxide semiconductor layer 110 in the vertical projection direction Z. According to the present invention, the thickness of the first patterned photoresist layer 114A is less than the thickness of the second patterned photoresist layer 114B. Specifically, the step of forming the first patterned photoresist layer 114A and the second patterned photoresist layers 114B on the conductive layer 112 in this embodiment includes forming the photoresist layer 114 (as shown in FIG. 6) on the conductive layer 112 blanketly first, using a halftone photomask 120 (as shown in FIG. 8) to perform a photolithography process to the photoresist layer 114 next, and forming the first patterned photoresist layer 114A and the second patterned photoresist layers 114B after the development, but not limited thereto.

For example, the halftone photomask 120 of this embodiment may include a transparent region 120a, a translucent region 120b and at least two opaque regions 120c. Taking a positive photoresist as an example for the photoresist material, the opaque regions 120c of the halftone photomask 120 may be disposed corresponding to the regions R1, R2 to form the second patterned photoresist layers 114B, the translucent region 120b of the halftone photomask 120 may be disposed corresponding to the region R3 to form the first patterned photoresist layer 114A, and the transparent region 120a of the halftone photomask 120 may be disposed corresponding to the region in which the portion of the photoresist layer 114 is required to be removed. Since the photoresist material corresponding to the opaque regions 120c and the translucent region 120b are exposed to different amounts of light, the thickness of the first patterned photoresist layer 114A is less than the thickness of the second patterned photoresist layers 114B as a result. In addition, after the photolithography process is performed, a portion of the conductive layer 112 is not covered by the first patterned photoresist layer 114A and the second patterned photoresist layers 114B. It is noteworthy that the halftone photomask 120 of this embodiment may further include other opaque regions 120c disposed corresponding to patterns of other conductive devices. The opaque regions 120c may further be disposed at regions predetermined to form the data line (or the signal lines) for example. Therefore, after development, the photoresist layer may further include a third patterned photoresist layer 114C (as shown in FIG. 7), connected to one of the second patterned photoresist layer 114B, for defining the pattern of the data line.

In other variant embodiments, the photoresist material may also be a negative photoresist. In this case, the halftone photomask may include an opaque region, a translucent region and at least two transparent regions. The transparent regions of the halftone photomask are used for forming the second patterned photoresist layers, the translucent region of the halftone photomask is used for forming the first patterned photoresist layer, and the opaque region of the halftone photomask is used for removing the photoresist material, but not limited thereto.

As shown in FIG. 9 and FIG. 10, Step S22 of FIG. 1 is executed next. A first etching process 122 is performed to remove the portion of the conductive layer 112 not covered by the first patterned photoresist layer 114A, the second patterned photoresist layers 114B and the third patterned photoresist layer 114C. Specifically, a first etchant is used in the first etching process 122 to remove a portion of the conductive layer 112. In this embodiment, the first etchant includes phosphoric acid, acetic acid and nitric acid, or namely PAN etchant, but not limited thereto. As the patterned metal oxide semiconductor layer 110 of this embodiment is covered by the first patterned photoresist layer 114A and the second patterned photoresist layers 114B during the first etching process 122, the patterned metal oxide semiconductor layer 110 is prevented from being in contact with the first etchant, such that the patterned metal oxide semiconductor layer 110 is further prevented from being damaged by the first etchant. It is noteworthy that the advantage of using the first etchant including phosphoric acid, acetic acid and nitric acid in Step S22 is that the etching rate is stable while removing a large area of the conductive layer 112, so that the overall etching performance is easier to be controlled during the etching process.

As shown in FIG. 11 and FIG. 12, Step S24 of FIG. 1 is executed next. The first patterned photoresist layer 114A is removed, and therefore a portion of the conductive layer 112 between the second patterned photoresist layers 114B is exposed. For example, the step of removing the first patterned photoresist layer 114A of this embodiment includes performing an ashing process 124, but not limited thereto. Specifically, as the thickness of the first patterned photoresist layer 114A is less than the thickness of the second patterned photoresist layers 114B in this embodiment, the first patterned photoresist layer 114A will be completely removed prior to the second patterned photoresist layers 114B when the ashing process 124 is performed to the first patterned photoresist layer 114A and the second patterned photoresist layers 114B together at the same time, and a portion of the second patterned photoresist layers 114B with a certain amount of thickness will be left to shield the region R1 and the region R2.

As shown in FIG. 13 and FIG. 14, Step S26 of FIG. 1 is performed next. A second etching process 126 is carried out to remove a portion of the conductive layer 112 not covered by the second patterned photoresist layers 114B to form the source 116 and the drain 118, and a portion of the patterned metal oxide semiconductor layer 110 that is covered by the first patterned photoresist layer 114A originally in FIG. 10 is exposed now. Specifically, a second etchant is used in the second etching process 126 to remove the portion of the conductive layer 112 between the second patterned photoresist layers 114B. In this embodiment, the second etchant includes hydrogen peroxide, but not limited thereto. Since the area of the region covered by the first patterned photoresist layer 114A (i.e. the region between the source 116 and the drain 118, or a channel region of the thin film transistor) is only about one thousandth to several hundredths of the area of a pixel, the loading of the second etchant can be effectively reduced in this embodiment. As a result, the issue of the variation of the etching rate can be avoided, and the problems of producing oxygen and temperature elevating during the process can be further avoided.

As shown in FIG. 15 and FIG. 16, Step S28 of FIG. 1 is performed next. The second patterned photoresist layers 114B are removed to expose the source 116 and the drain 118. Since the metal oxide semiconductor thin film transistor manufactured by the method of this embodiment may be applied to the display panel, as the above mentioned, the data line DL (or signal line) can be formed with the source 116 and the drain 118 together at the same time. The third patterned photoresist layer 114C can be removed together while removing the second patterned photoresist layers 114B to expose the data line DL. The data line DL is extended along a second direction D2 and is connected to the source 116. The data line DL, the source 116 and the drain 118 may belong to the same conductive layer 112. The data line DL, the source 116 and the drain 118 may be covered by the second patterned photoresist layers 114B and the third patterned photoresist layer 114C, and the second patterned photoresist layers 114B and the third patterned photoresist layer 114C may belong to the same patterned photoresist layer. The data line DL, the source 116 and the drain 118 may be formed by the first etching process 124 and the second etching process 126.

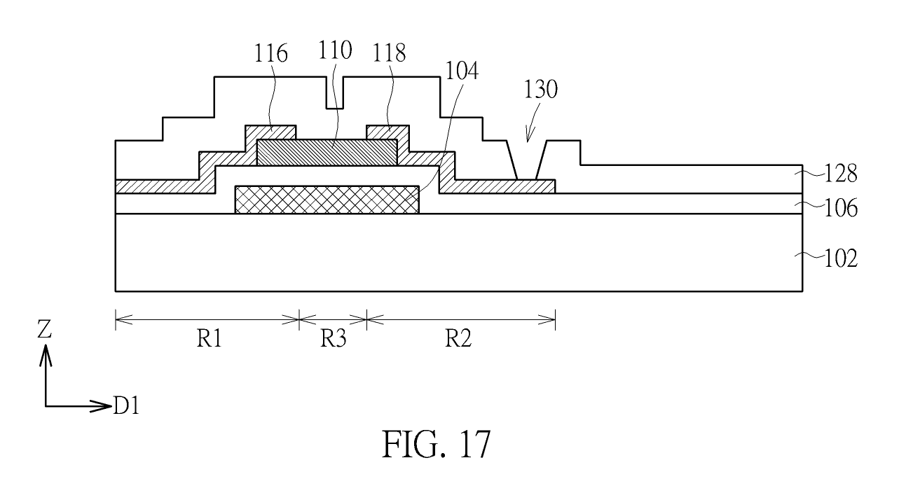

As shown in FIG. 17, a patterned dielectric layer 128 is formed on the patterned metal oxide semiconductor layer 110, the source 116, the drain 118 and the gate insulating layer 106 after the step of removing the second patterned photoresist layers 114B. The dielectric layer 128 has at least one contact hole 130 exposing a portion of the drain 118. In this embodiment, the step of forming the patterned dielectric layer 128 may include depositing a dielectric material blanketly (such as adopting the PECVD process), and forming the contact hole 130 by the photolithography and etching process. The material of the dielectric layer 128 of this embodiment may include an inorganic insulating material, such as silicon oxide, silicon nitride or silicon oxynitride, but not limited thereto. The material of the dielectric layer 128 may include an organic insulating material or an organic/inorganic hybrid insulating material in various embodiments.

As shown in FIG. 18 and FIG. 19. A pixel electrode PE is formed on the dielectric layer 128 next, wherein the pixel electrode PE is electrically connected to the drain 118 through the contact hole 130. The material of the pixel electrode PE may include indium tin oxide, indium zinc oxide, aluminum zinc oxide or other suitable transparent conductive materials. For example, the method of forming the pixel electrode PE may include depositing the transparent conductive material layer by sputtering, and then performing the photolithography and etching process to the transparent conductive material layer to form the pixel electrode PE.

Above all, the manufacturing method of the metal oxide semiconductor thin film transistor of the present invention includes the steps shown in FIG. 1:

Step S10: providing a substrate;

Step S12: forming a gate on the substrate;

Step S14: forming a gate insulating layer on the gate;

Step S16: forming a patterned metal oxide semiconductor layer on the gate insulating layer, wherein the patterned metal oxide semiconductor layer partially overlaps the gate;

Step S18: forming a conductive layer on the patterned metal oxide semiconductor layer;

Step S20: forming a first patterned photoresist layer and two second patterned photoresist layers on the conductive layer, wherein the second patterned photoresist layers are respectively disposed at a region predetermined to form a source and a region predetermined to form a drain, and the first patterned photoresist layer is disposed between the second patterned photoresist layers;

Step S22: performing a first etching process to remove a portion of the conductive layer not covered by the first patterned photoresist layer and the second patterned photoresist layers;

Step S24: removing the first patterned photoresist layer to expose a portion of the conductive layer disposed between the second patterned photoresist layers;

Step S26: performing a second etching process to remove a portion of the conductive layer not covered by the second patterned photoresist layers to form the source and the drain; and

Step S28: removing the second patterned photoresist layers.

Comparing to the conventional methods, the method of the present invention includes two etching processes to form the source and the drain. The first etchant including phosphoric acid, acetic acid and nitric acid are used in the first etching process to remove a large area of the conductive layer. Meanwhile, the patterned metal oxide semiconductor layer is covered by the first patterned photoresist layer and the second patterned photoresist layers, and therefore the patterned metal oxide semiconductor layer can be prevented from being damaged by the first etchant effectively and further prevented the thin film transistor from being broken down. In addition, the etching rate can be kept in stable during the etching process when the etchant including phosphoric acid, acetic acid and nitric acid are used. Next, the second etchant including hydrogen peroxide is used in the second etching process to remove a portion of the conductive layer not covered by the second patterned photoresist layers. Since the area of the region covered by the first patterned photoresist layer is only about several hundredths of the area of a pixel, the loading of the second etchant can be effectively reduced. Accordingly, the issue of the variation of the etching rate can be avoided, the problems of producing oxygen and temperature elevating during the process can be avoided, and thus the explosion or the apparatus damage can be prevented.

Those skilled in the art will readily observe that numerous modifications and alterations of the device and method may be made while retaining the teachings of the invention. Accordingly, the above disclosure should be construed as limited only by the metes and bounds of the appended claims.

1. A manufacturing method of a metal oxide semiconductor thin film transistor, comprising:
providing a substrate;
forming a gate on the substrate;
forming a gate insulating layer on the gate;
forming a patterned metal oxide semiconductor layer on the gate insulating layer, wherein the patterned metal oxide semiconductor layer partially overlaps the gate;
forming a conductive layer on the patterned metal oxide semiconductor layer;
forming a first patterned photoresist layer and two second patterned photoresist layers on the conductive layer, wherein the second patterned photoresist layers are respectively disposed at a region predetermined to form a source and a region predetermined to form a drain, and the first patterned photoresist layer is disposed between the second patterned photoresist layers;
performing a first etching process to remove a portion of the conductive layer not covered by the first patterned photoresist layer and the second patterned photoresist layers, wherein the first etching process comprises an etching process using a first etchant;
removing the first patterned photoresist layer to expose a portion of the conductive layer disposed between the second patterned photoresist layers;
performing a second etching process to remove a portion of the conductive layer not covered by the second patterned photoresist layers to form the source and the drain, wherein the second etching process comprises another etching process using a second etchant, and the first etchant is different from the second etchant; and
removing the second patterned photoresist layers.

2. The manufacturing method of the metal oxide semiconductor thin film transistor according to claim 1, wherein a thickness of the first patterned photoresist layer is less than a thickness of the second patterned photoresist layers.

3. The manufacturing method of the metal oxide semiconductor thin film transistor according to claim 1, wherein the step of forming the first patterned photoresist layer and the second patterned photoresist layers on the conductive layer comprises:
forming a photoresist layer on the conductive layer; and
performing a lithography process to the photoresist layer with a halftone photomask to form the first patterned photoresist layer and the second patterned photoresist layers.

4. The manufacturing method of the metal oxide semiconductor thin film transistor according to claim 1, wherein the first etchant comprises phosphoric acid, acetic acid and nitric acid.

5. The manufacturing method of the metal oxide semiconductor thin film transistor according to claim 1, wherein the second etchant comprises hydrogen peroxide.

6. The manufacturing method of the metal oxide semiconductor thin film transistor according to claim 1, wherein the step of removing the first patterned photoresist layer comprises performing an ashing process.

7. The manufacturing method of the metal oxide semiconductor thin film transistor according to claim 1, further comprising:
forming a dielectric layer on the patterned metal oxide semiconductor layer, the source, the drain and the gate insulating layer after the step of removing the second patterned photoresist layers, wherein the dielectric layer has at least one contact hole exposing a portion of the drain; and
forming a pixel electrode on the dielectric layer, wherein the pixel electrode is electrically connected to the drain through the contact hole.

8. The manufacturing method of the metal oxide semiconductor thin film transistor according to claim 1, wherein the patterned metal oxide semiconductor layer comprises indium gallium zinc oxide (IGZO).

9. The manufacturing method of the metal oxide semiconductor thin film transistor according to claim 1, wherein the substrate comprises a glass substrate.
